(19) United States
(12) Patent Application Publication
(10) Pub. No.: US 2006/0134887 A1
(43) Pub. Date: Jun. 22, 2006

(54) Method of manufacturing a slice of semiconductor

(75) Inventors: Jean-Noel Audoux, Orleans (FR); Denis Groeninck, Ligny le Ribault (FR)

Correspondence Address: OSHA LIANG L.L.P., 1221 MCKINNEY STREET, SUITE 2800, HOUSTON, TX, 77010, US

(73) Assignee: AXALTO SA, Montrouge Cedex (FR)

(21) Appl. No.: 10/545,357

(22) PCT Filed: Feb. 10, 2004
(86) PCT No.: PCT/IB04/00335

§ 371 Date: Aug. 11, 2005

(30) Foreign Application Priority Data
Feb. 11, 2003 (EP) 03290336.1
Aug. 28, 2003 (EP) 03077862.5

(51) Int. Cl. H01L 21/78; H01L 21/50

(52) U.S. Cl. 438/465; 438/460; 438/113

(57) ABSTRACT

A method of manufacturing an integrated circuit element from a silicon wafer, the silicon wafer having an active face and an inactive face, a passivation layer being deposited on the active face, where the method includes: an organic-layer-depositing step, in which an organic layer is deposited on the inactive face of the silicon wafer using a spin coating technique to obtain a sandwich-like structure, the passivation layer and the organic layer having substantially the same thickness, and a wafer-sawing step, in which a slice of the silicon wafer is sawed so as to obtain a several integrated circuit elements.

### FIELD OF THE INVENTION

The invention concerns a method of manufacturing a slice of semiconductor. The invention also concerns a slice of semiconductor comprising an active face and an inactive face. The slice of semiconductor is, for example, a silicon wafer. The invention also concerns a piece of slice of semiconductor, for example, an integrated circuit element. The invention also concerns a portable object of the smart card type. The invention can be applied, in particular in the semiconductor industry, in the smart card industry and in any thin chip application.

### BACKGROUND OF THE INVENTION

A wafer generally comprises an active face and inactive face. The active face is provided with active elements, for example, integrated circuit devices. The active face is also provided with contact pads. The active face is generally already coated with a passivation layer in order to better protect the active face. A passivation layer is generally made of SiO2 or Si3N4.

FIG. 1-A illustrates a method of manufacturing a smart card comprising the following steps:
A wafer testing step TEST, in which the wafer is electrically tested;
A wafer thinning step THIN, in which the inactive face of the wafer is thinned;
A wafer mounting step MOUNT, in which the wafer is mounted on a mounting support to be manufactured;
A wafer sawing step SAW, in which the wafer is sawed so as to obtain a plurality of active elements;
A pick and place step PP, in which an active element is picked and then placed, for example, on a lead-frame or on any other package type;
A connecting step CON, in which the active element is electrically connected to contact areas of the leadframe; and
An encapsulating step ENCAP, in which the connected active element is coated with a resin material so as to obtain a module.
An embedding step EMB, in which the module is embedded in a card body so as to obtain a smart card.

### SUMMARY OF THE INVENTION

It is an object of the invention to enhance the quality and to reduce the costs.

According to one aspect of the invention, a method of manufacturing a slice of semiconductor, the slice of semiconductor comprising an active face and an inactive face, a passivation layer being deposited on the active face, is characterized in that the method comprises an organic-layer-depositing step, in which an organic layer is deposited on the inactive face of slice of semiconductor.

The slice of semiconductor is, for example, a silicon wafer. The organic layer is, for example, made of polyimide.

By providing the inactive face of the wafer with an organic layer, a composite structure (organic/mineral/organic) is obtained. Therefore the mechanical stress induced by the passivation layer on the active face is reduced. The organic layer compensates the initial wafer stress. Thus the wafer bow and warping is reduced. The flatness of the wafer is therefore improved.

According to another advantage of the invention, the organic layer is made of an organic material. Thus the depositing step can be done using a spin coating process, which is easy to implement and cost effective.

Thus the invention allows a reduction of the cost and an enhanced quality.

### BRIEF DESCRIPTION OF THE DRAWINGS

FIG. 1-A illustrates a method of manufacturing a smart card;

FIG. 1-B illustrates method of manufacturing a slice of semiconductor; and

FIG. 2 illustrates the composite structure of a silicon wafer in a particular embodiment.

### DETAILED DESCRIPTION

A silicon wafer generally comprises an active face provided with various integrated circuit elements and an inactive face. A passivation layer is deposited on the active face in order to protect the integrated circuit elements. The passivation layer generally has a thickness smaller than 10 μm. The thickness is comprised, for example, between 2 μm and 3 μm.

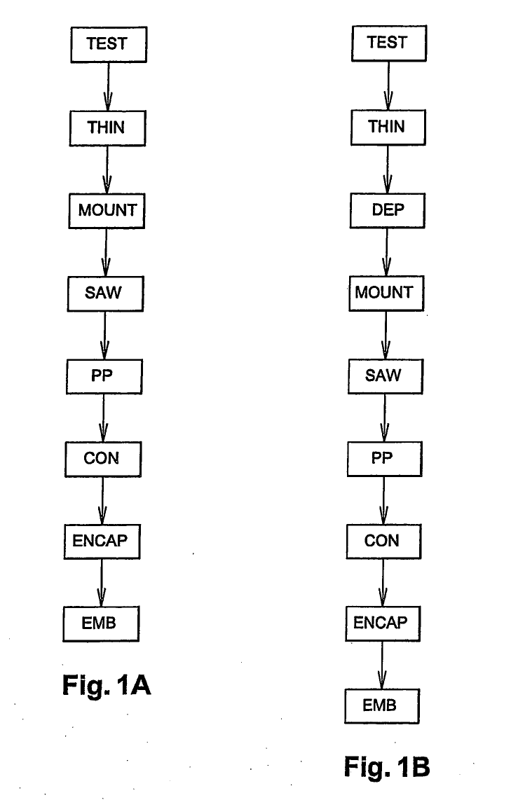

Silicon is a very brittle material, especially for thin chip application. During most of the manufacturing steps illustrated in FIG. 1-A, the silicon is made fragile due to mechanical constraints faced. Chip breakage risk is thus very high.

FIG. 1B illustrates a method of manufacturing a slice of semiconductor according to the invention.

In an organic-layer-depositing step DEP, the inactive face of a silicon wafer is provided with an organic layer so as to obtain a coated silicon wafer.

The thickness of the organic layer is preferably smaller than 10 μm, and advantageously comprised between 2 μm and 5 μm. The organic layer can be, for example, a polyimide, a thermic curing resin (epoxy basis), UV curing resin, an adhesive or a glue. The organic-layer-depositing step DEP can be introduced, for example, between a wafer-thinning step THIN and a wafer-mounting step MOUNT.

Then, in a wafer-sawing step SAW, the coated silicon wafer is sawed so as to obtain a plurality of integrated circuit elements.

In a pick and place step PP, the circuit elements are picked from the mounting support and placed on a support layer provided with contact elements. The support layer is, for example, a leadframe.

In a connecting step CON, the circuit elements are connected to the contact elements of the support layer so as to obtain connected circuit elements. The connecting step can be made using, for example, a wire bonding technique or a flip chip technique.

In an encapsulating step ENCAP, the connected circuit elements are encapsulated with a resin material so as to protect the circuit elements.

In an embedding step EMB, the connected circuit elements are embedded in a card body so as to obtain a smart card.

By providing the inactive face of the wafer with an organic layer, a composite structure (organic/mineral/organic) is obtained.

Therefore the mechanical stress induced in particular by the passivation layer and the initial wafer bow, is reduced. The organic layer compensates the initial wafer stress. Thus the wafer bow and warping is reduced. The flatness of the wafer is therefore improved.

In addition, due to this composite structure, chipping and crack propagation into silicon is also reduced in particular during the wafer-mounting step and the wafer-sawing step. The thus obtained integrated circuit elements have also composite structure (organic/mineral/organic) and are therefore more rigid.

Due to this global mechanical behaviour improvement, the lifetime of the smart card is significantly increased. During, for example, the “3wheels” test as defined in the ISO standards 7810 and 10373.1, the stress applied on the chip is reduced by 9%. In this case, the thickness of the passivation layer was comprised between 2 μm and 3 μm. The thickness of the organic layer on the inactive face was comprised between 3 μm and 5 μm.

The description hereinbefore illustrates a method of manufacturing a slice of semiconductor. The slice of semiconductor comprises an active face and an inactive face. A passivation layer is deposited on the active face. The method comprises an organic-layer-depositing step, in which an organic layer is deposited on the inactive face of the slice of semiconductor.

The slice of semiconductor is, for example, made of silicon. It can be, in particular a silicon wafer. The organic layer can be any organic layer than can be deposited on a slice of semiconductor, for example, a polyimide, a thermic curing resin (epoxy basis), UV curing resin, an adhesive or a glue.

According to another aspect of the invention, a slice of semiconductor comprising an active face and an inactive face, the active face being provided with a passivation layer, is characterized in that the inactive face is provided with an organic layer.

According to another aspect of the invention, an integrated circuit element comprising an active face and an inactive face, a passivation layer being deposited on the active face, is characterized in that the inactive face is provided with an organic layer.

According to another aspect of the invention, a portable object of the smart card type, is characterized in that the smart card comprises the above-mentioned integrated circuit element.

The portable object can be, for example, a smart card or any other portable element comprising an integrated circuit. It can be, for example, a small device provided with a flash memory.

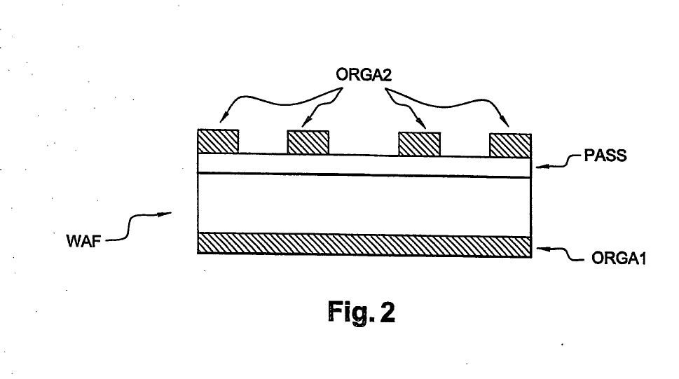

As illustrated in FIG. 2, an organic layer ORGA2 can also be deposited on the passivation layer so as to optimise the geometry of the composite structure (ORGA1, WAF, PASS+ORGA2). Advantageously this organic layer ORGA2 can be made of a photosensitive resin. In this respect, a photo-lithographic process (photosensitive resin coating by liquid spinning, curing, exposure, development, etc. . . .) can, for example, be used. By using a photosensitive material, openings can be created within the organic layer ORGA2 above, for example, the contact pads of the active surface ACTIV of the wafer WAF.

In the above-mentioned description, the organic-layer depositing step is made before the wafer-sawing step. But the organic-layer depositing step can be made after the wafer-sawing step, advantageously just before the pick and place step.

In the above-mentioned description, the wafer-thinning step is made before the organic-layer depositing step. In this respect, for example, the wafer can be first sawed, entirely or not, then thinned and only then an organic layer is deposited on the inactive face.

According to another aspect of the invention a shielding layer can be placed on the active face of the wafer. Advantageously the shielding layer is made of the same material than the wafer. Advantageously, the shielding layer is provided with holes being located flush with at least one integrated circuit element of the active face of the wafer. In this case the photosensitive resin can be deposited on the shielding layer.

1.-10. (canceled)

11. A method of manufacturing an integrated circuit element from a silicon wafer, the silicon wafer comprising an active face and an inactive face, a passivation layer being deposited on the active face, wherein the method comprises the following steps:
a. an organic-layer-depositing step, in which an organic layer is deposited on the inactive face of the silicon wafer using a spin coating technique so as to obtain a sandwich-like structure, the passivation layer and the organic layer having substantially the same thickness; and
b. a wafer-sawing step, in which a slice of the silicon wafer is sawed so as to obtain a plurality of integrated circuit elements.

12. The method according to claim 1, wherein the organic layer is a polyimide.

13. The method according to claim 1, wherein the active face is provided with a second organic layer.

14. The method according to claim 4, wherein the second organic layer is made of a photosensitive resin.

15. A portable object of the smart card type, wherein the portable object comprises the integrated circuit element obtained by the method of claim 1.
